(19) United States
(12) Patent Application Publication
(10) Pub. No.: US 2018/0166311 A1
(43) Pub. Date: Jun. 14, 2018

(54) NEW REPAIR METHOD FOR ELECTROSTATIC CHUCK

(71) Applicant: Applied Materials, Inc., Santa Clara, CA (US)

(72) Inventor: Wendell Glen BOYD, JR., Morgan Hill, CA (US)

(21) Appl. No.: 15/375,577

(22) Filed: Dec. 12, 2016

(51) Int. Cl. H01L 21/683; C23C 4/02; C23C 4/134; C23C 4/18; C23C 4/04

(52) U.S. Cl. CPC H01L 21/6833; C23C 4/02; C23C 4/04; C23C 4/18; C23C 4/134

(57) ABSTRACT

Implementations of the present disclosure relate to a method of refurbishing a sinter or plasma sprayed electrostatic chuck. Initially, a portion of a used electrostatic chuck body is removed to expose a base surface. Then, a layer of new dielectric material is deposited onto the base surface using a suspension slurry plasma spray process. The suspension slurry plasma spray process atomizes a suspension slurry of a nano-sized dielectric material into a stream of droplets, and then the stream of droplets is injected into a plasma discharge to form partially melted drops. The partially melted drops is projected onto the base surface to form a layer of dielectric material thereon. Thereafter, material of the layer of the new dielectric material is selectively removed to form mesas. The refurbished electrostatic chuck is ready to return to service after cleaning.

### BACKGROUND

### Field

Implementations of the present disclosure generally relate to a refurbished electrostatic chuck and a method for refurbishing a sinter electrostatic chuck.

### Description of the Related Art

Electrostatic chucks are useful in the manufacture of semiconductor devices. The electrostatic chuck permits that substrate to remain in a fixed location on the electrostatic chuck during processing by electrostatically clamping the substrate to the chuck.

The electrostatic chuck typically has an electrode embedded within a dielectric material. The topmost surface of the electrostatic chuck has a plurality of mesas (i.e., projections) upon which the substrate will sit during processing. Over time, the mesas may wear down and the electrostatic chuck will not be as effective. The electrical properties the electrostatic chuck may be jeopardized by a crack in the dielectric material or the dielectric material may be compromised by a chemical or plasma attack causing the dielectric material to breakdown. When the mesas wear down, the substrate has more contact which causes a temperature fluctuation which affects the uniformity within the substrate. The temperature of the electrostatic chuck also compensates for this and increases its temperature. Another effect from worn out mesas is the backside gas cooling cannot get underneath the substrate which also affects the uniformity within the substrate. This non-uniformity cause yield loss and can change the device performance. The electrostatic chuck is thus no longer useful and is typically discarded or refurbished. It would be beneficial to avoid the expense of purchasing a new electrostatic chuck.

Chemical and process bi-products change dielectric properties which increases or decreases the chucking force and leads to broken substrates or wafer handling issues. The standard refurbishment process is to remove the remaining mesas and 5-50 microns of the dielectric material and recreate the mesas. This makes the dielectric material thinner, allowing it to be done only a couple of times. When the dielectric materials get too thin, high voltage punch through would occur.

Sinter electrostatic chucks are used to reduce the dielectric material and lower chucking voltages required to chuck the substrate. Conventional plasma spray cannot be used for repair because of the porosity issue associated with the current processes.

To avoid the expense of purchasing a new sinter electrostatic chuck, a refurbishment process can be performed to refurbish the electrostatic chuck by removing a desired thickness of the dielectric material (including the mesas formed thereon), followed by a bead blasting and masking process to form mesas in the dielectric material. With this approach, however, the number of the refurbishment process that can be performed is limited because the dielectric material will become thinner in thickness after a number of process cycles.

Therefore, there is a need in the art for an improved method of refurbishing the electrostatic chuck to heal the cracks in the dielectric material.

### SUMMARY

Implementations of the present disclosure relate to a method of refurbishing a sinter or plasma sprayed electrostatic chuck. In one implementation, the method for refurbishing an electrostatic chuck is disclosed. The method includes removing a first portion of an electrostatic chuck body to expose a second portion of the electrostatic chuck body, wherein the first portion has a first depth below a top surface of the electrostatic chuck body and the second portion has a second depth below the top surface of the electrostatic chuck body, depositing a layer of dielectric material onto the second portion using a suspension slurry plasma spray process, and selectively removing material from the layer of dielectric material to establish a new top surface. The suspension slurry plasma spray process includes producing a plasma discharge, atomizing a suspension slurry of a dielectric material into a stream of droplets, wherein the suspension slurry comprises nano-sized solid particles of the dielectric material dispersed into a liquid or semi-liquid carrier substance, injecting the stream of droplets into the plasma discharge to form partially melted drops, and forming a layer of dielectric material onto the exposed second portion by projecting the partially melted drops onto the second portion of the electrostatic chuck body.

In another implementation, the method includes (a) removing a portion of an electrostatic chuck body to expose a base surface of the electrostatic chuck body, (b) depositing a layer of dielectric material onto the base surface using a suspension slurry plasma spray process, the suspension slurry plasma spray process comprising producing a plasma discharge, atomizing a suspension slurry of a dielectric material into a stream of droplets, the suspension slurry comprising nano-sized solid particles of the dielectric material dispersed into a liquid or semi-liquid carrier substance, injecting the stream of droplets into the plasma discharge directly to form partially melted drops, and forming a layer of dielectric material onto the base surface by accelerating the partially melted drops with the plasma discharge towards the base surface of the electrostatic chuck body, and (c) roughening the layer of dielectric material, and (d) selectively removing material from the layer of dielectric material to establish a new top surface.

In yet another implementation, a refurbished electrostatic chuck refurbished by the method described in the above implementations is provided.

### BRIEF DESCRIPTION OF THE DRAWINGS

So that the manner in which the above-recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1A is a schematic top view of a used Johnson-Rahbek type electrostatic chuck prior to refurbishment.

FIG. 1B is a cross-sectional view of the used electrostatic chuck of FIG. 1A.

FIGS. 2 to 7 are cross-sectional views of the electrostatic chuck of FIGS. 1A and 1B at various stages of refurbishment according to implementations of the present disclosure.

FIG. 8 illustrates a flow chart of a refurbishment process for refurbishing a used electrostatic chuck according to implementations of the disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

Implementations of the present disclosure generally relate to a method of refurbishing a sinter or plasma sprayed electrostatic chuck. Initially, a predetermined amount of dielectric material (e.g., AlO) is removed from the used electrostatic chuck to leave a base surface. Then, the base surface is deposited with a dielectric material by suspension slurry plasma spray using nanometer powder of the dielectric material. A portion of the new dielectric layer is then removed by masking and bead blasting to form new mesas. After removing the mask, edges of the mesas may be smoothed and the refurbished electrostatic chuck is ready to return to service after cleaning.

Suitable sinter or plasma spray electrostatic chucks that may be refurbished according to the implementations discussed herein include Coulomb or Johnson-Rahbek electrostatic chucks available from Applied Materials, Inc., Santa Clara, Calif. It is to be understood that the implementations discussed herein are equally applicable to other types of electrostatic chucks, including those available from other manufacturers.

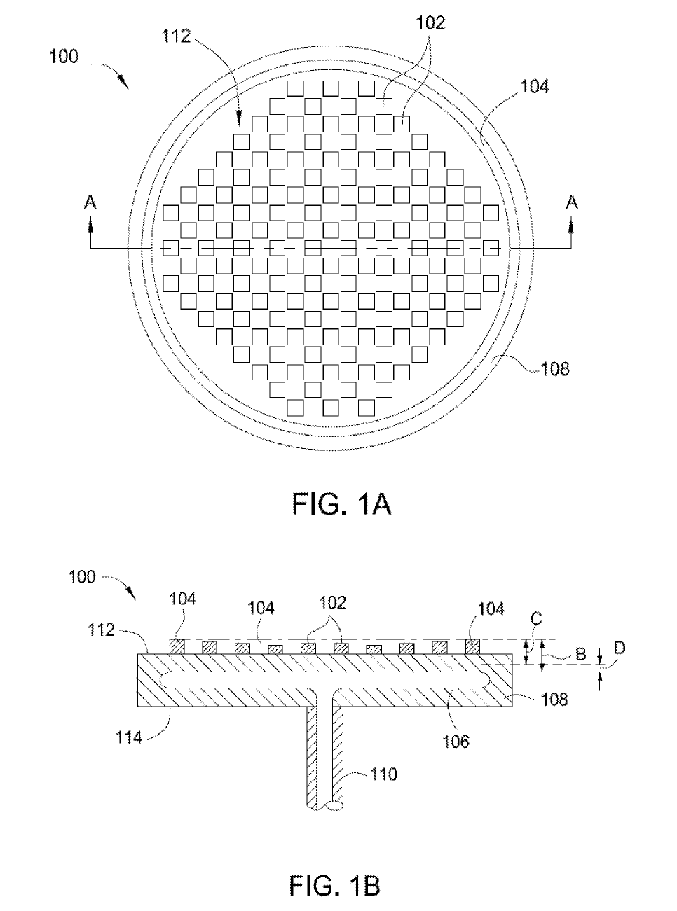

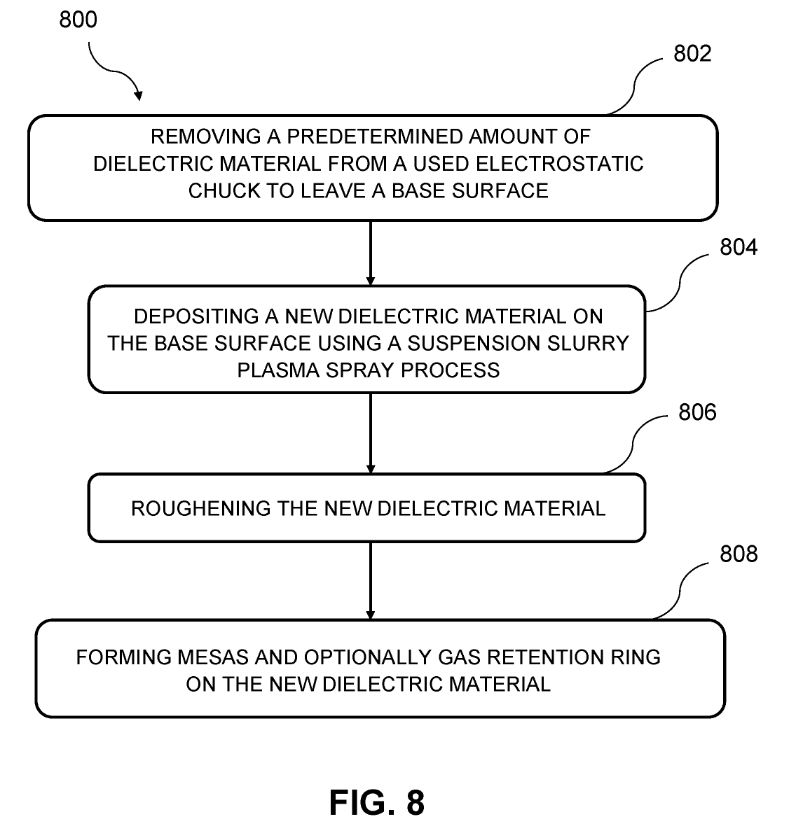

FIG. 8 depicts a flow chart of a refurbishment process 800 for refurbishing a used electrostatic chuck according to implementations of the disclosure. FIG. 8 is illustratively described with reference to FIGS. 1A-1B and FIGS. 2-7, which show cross-sectional views of a used electrostatic chuck during various stages of refurbishment process according to the flow chart of FIG. 8. The refurbishment process begins at block 802 by removing a predetermined amount of dielectric material from the used electrostatic chuck to leave a base surface.

FIG. 1A is a schematic top view of a used Coulomb or Johnson-Rahbek type sinter or plasma sprayed electrostatic chuck 100 prior to refurbishment. FIG. 1B is a cross-sectional view of the used electrostatic chuck 100 of FIG. 1A. As shown in FIG. 1B, the electrostatic chuck 100 has a chuck body 108 that includes a top surface 112 and a bottom surface 114. The top surface 112 includes a plurality of mesas 102 extending from the chuck body 108 of the electrostatic chuck 100. The mesas 102 may comprise the same material as the chuck body 108. In one implementation, the chuck body 108 is comprised of dielectric material such as aluminum oxide, aluminum nitride, or suitable ceramic material which is excellent in heat resistance or corrosion resistance. If desired, the chuck body 108 may have one or more dielectric layers formed as a unified structure for supporting a substrate. The term “layer” includes the case where a layer is continuously formed and the case where a layer is discontinuously formed.

In the implementation shown in FIGS. 1A and 1B, the chuck body 108 is a single aluminum oxide sintered body. The aluminum oxide sintered body can be formed by providing a mixture containing aluminum oxide serving as a main raw material in an organic solvent to provide a slurry, and drying the slurry to provide prepared powder. The prepared powder is compacted or fired by hot pressing to provide a dense aluminum oxide sintered body. In one exemplary implementation, the chuck body 108 is formed from a composition of 95 wt % or more (e.g., 99 wt % or more) of aluminum oxide as a major component. The chuck body 108 may contain other element, such as yttria, titanium, or a rare-earth element, to provide a volume resistivity suitable for a Johnson-Rahbek electrostatic chuck, a volume resistivity suitable for a Coulomb electrostatic chuck, or a volume resistivity therebetween. While aluminum oxide is particularly discussed in this disclosure, it is to be understood that the refurbishment method of the present disclosure is applicable to electrostatic chucks comprising other dielectric materials.

A gas retention ring 104 may be optionally formed on the top surface 112. The gas retention ring 104 may extend from the top surface 112 and encircles the area where the mesas 102 are disposed. Both the mesas 102 and the gas retention ring 104 may comprise the same dielectric material as the chuck body 108. Embedded within the chuck body 108 is an electrode 106 that couples to a power source through a stem 110 coupled to the bottom surface 114 of the electrostatic chuck 100.

As shown in FIG. 1B, some of the mesas 102 are wore down and have a different height above the chuck body 108 due to the chemical or plasma attack during processing. Therefore, any substrate disposed on the electrostatic chuck 100 may not be held substantially flat, which in turn prevents the substrate disposed on the electrostatic chuck 100 from being uniformly chucked and processed.

In order to refurbish the electrostatic chuck 100, an amount of material to be removed needs to be determined. A distance, shown by arrow “B”, between the electrode 106 and the highest point of the mesas 102 or gas retention ring 104 (if used), is determined by measuring the capacitance of the electrostatic chuck 100. A predefined amount of material, shown by arrow “D” is desired to remain over the electrode 106 after the material is removed to prevent accidental exposure of the electrode 106. Thus, the amount of material to be removed, shown by distance “C”, may be determined by subtracting distance “D” from distance “B”. In some exemplary implementations, the amount of material to be removed is about 10 microns to about 50 microns in thickness, measuring from the top surface 112 of the chuck body 108.

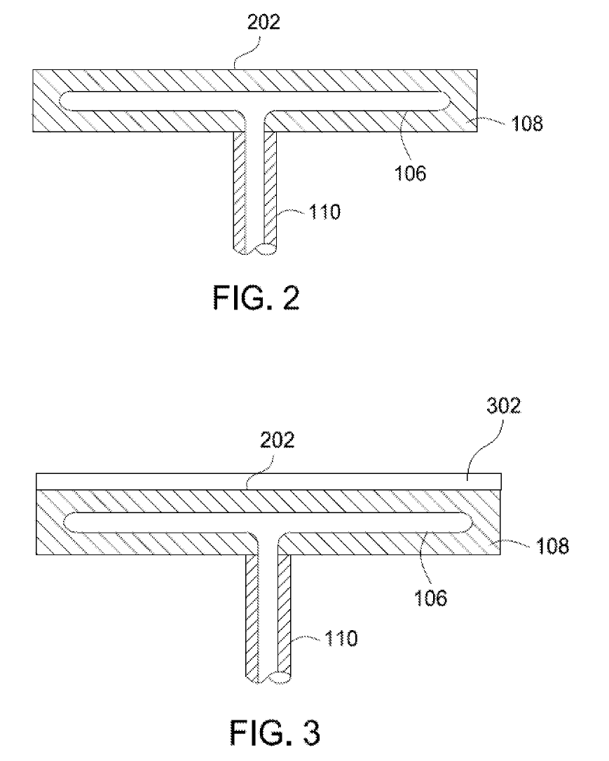

Once the amount of material to remove is determined, the electrostatic chuck 100 is processed to remove the mesas 102, gas retention ring 104 and a portion of the material of the chuck body 108 to leave a base surface 202, as shown in FIG. 2, which is the distance “D” above the electrode 106. The distance “D” may be between about 20 microns to about 50 microns from the electrode 106. The material may be removed by grinding or polishing, or any other technique suitable for removing the materials.

At block 804, a new dielectric material 302 is deposited on the base surface 202 using a suspension slurry plasma spray process, as shown in FIG. 3. The new dielectric material 302 may have a thickness of about 20 microns to about 60 microns. A thicker or thinner dielectric material 302 is contemplated depending on the application. The new dielectric material 302 should have the same or substantial identical resistivity as the original dielectric material that forms the chuck body 108. Suitable dielectric materials that may be used include aluminum oxide, aluminum nitride, or ceramic material. In various implementations, the new dielectric material 302 and the chuck body are formed from the same material. In one exemplary implementation, the new dielectric material 302 is aluminum oxide. Once the appropriate material is selected for the Johnson-Rahbek electrostatic chuck, the new dielectric material 302 is coated onto the base surface 202 using the suspension slurry plasma spray process.

The suspension slurry plasma spray process described herein is capable of producing a material deposit on the base surface 202 to form either a protective coating or a near net shape body, or produce a powder of a given material. The material may be supplied to a plasma discharge in the form of suspension slurry comprising small nano-sized solid particles or powders that are dispersed into a solvent or other liquid or semi-liquid carrier substance. The plasma discharge may be formed inductively or capacitively. The nano-sized solid particles or powders may have a diameter of about 1 micron to about 10 nanometer. In cases where aluminum oxide is desired, the material is an aluminum oxide powder having nano-sized particles. The suspension may be brought or injected into the plasma discharge by an atomizing probe. The atomizing probe uses a pressurized gas to shear the suspension and thus atomize it into a stream of fine droplets.

When the stream of fine droplets of suspension reach the plasma discharger, the solvent first evaporates and the vapors thus formed decomposes under the extreme heat of the plasma. The remaining aerosol of small solid particles then agglomerate into drops which are either totally or partially melted. The plasma discharge accelerates the molten drops, which accumulate kinetic energy. Carried by this kinetic energy, the molten drops are entrained by the plasma discharge and projected against the base surface 202 on which they solidify, forming a layer of the dielectric material having a thickness of about 20 microns to about 60 microns. Alternatively, the molten drops can be solidified in flight and collected into a vessel to produce a powder of that material.

The suspension slurry plasma spray process has the ability to drive the porosity out of the dielectric material. It has been observed that the porosity of the dielectric material 302 can be reduced to 1% or below. The porosity is critical to stop high voltage break down on thin dielectrics. Plasma spray in the past had to be annealed or compressed under pressure to achieve the low porosity that is required for an electrostatic chuck. With this improved refurbishment process using the suspension slurry plasma spray, the porosity of the aluminum oxide can be driven out more effectively, meaning plasma spray is now feasible without annealing or compressing under pressure.

The suspension slurry plasma spray process has the advantage over the conventional plasma spray techniques because the suspension slurry plasma spray process eliminates the numerous, complex and time consuming steps involved in the preparation of a costly powder by atomizing the suspension slurry comprising small nano-sized solid particles or powders into a stream of fine droplets to be injected directly into the plasma. Therefore, the droplets are dried in flight, calcined and melted in a single step. In contrast, the conventional plasma spray requires powder to be injected in a plasma jet by means of a carrier gas. Most importantly, the dielectric thickness is always the same even after multiple cycles of refurbishment process.

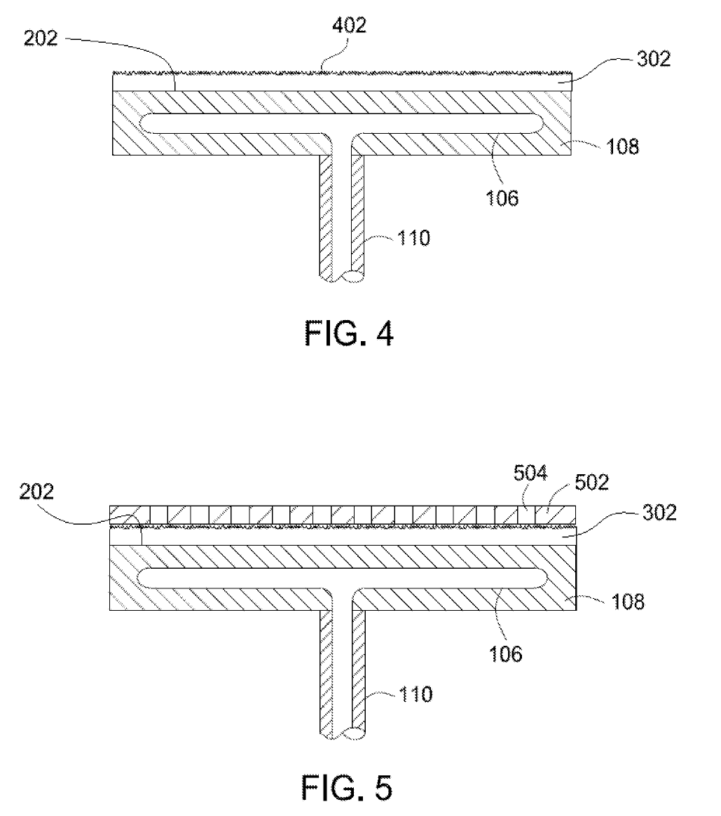

At block 806, the new dielectric material 302 is roughened to a surface roughness of between about 2 microinches and about 10 microinches, which results in roughened surface 402 as shown in FIG. 4. The new dielectric material 302 may be roughened by bead blasting or any suitable polishing technique under minimum force.

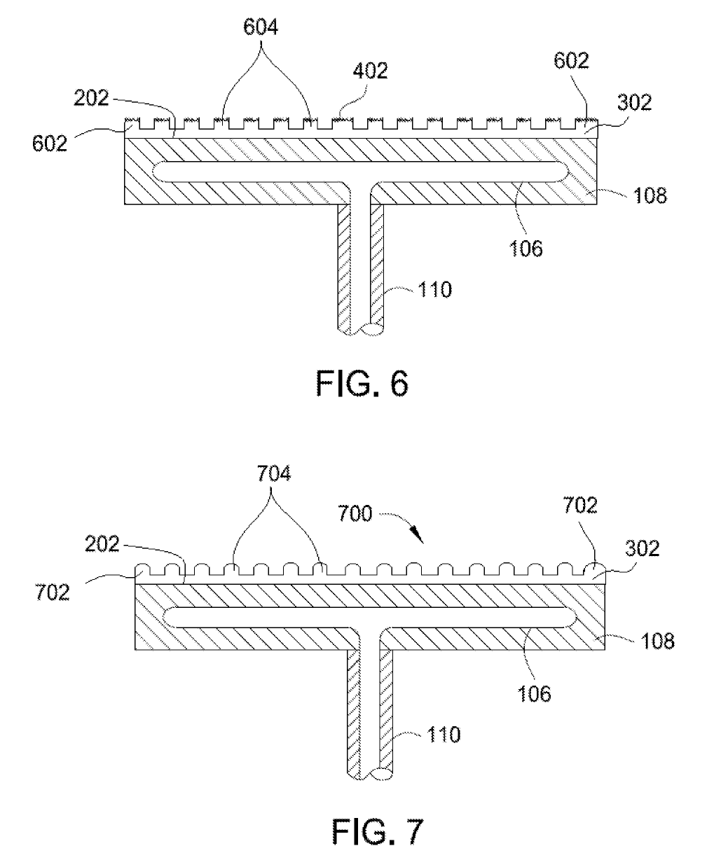

At block 808, after the roughened surface 402 is formed, the mesas and gas retention ring (optional) are formed. To form the mesas and gas retention ring, portions of the new dielectric material 302 are selectively removed. To selectively remove portions of the new dielectric material 302, a mask 502 is placed over the new dielectric material 302, as shown in FIG. 5. During the process of forming the mesas 604 and gas retention ring 602, gas grooves, embossments and other geometries may be formed as desired. The mask 502 has openings 504 that correspond to the areas adjacent to the location where the mesas and gas retention ring will be formed. The exposed new dielectric material 302 is then bead blasted through the openings 504 formed through the mask 502. The mask 502 is removed to leave the newly formed mesas 604 and gas retention ring 602, as shown in FIG. 6.

The mesas 604 and gas retention ring 602 may have sharp edges or burrs that may scratch the back of the substrate during processing and create undesired particles. Therefore, the mesas 604 and gas retention ring 602 may be polished with a soft polishing pad under minimum force to round the sharp corners, to remove the burrs and to leave the finished mesas 704 and retention ring 702 as shown in FIG. 7. Thus, the refurbished electrostatic chuck 700 is again ready for operation.

The refurbished electrostatic chuck 700 comprises the original chuck body 108 having the electrode 106 embedded therein and a new dielectric material 302 disposed thereover with a top surface that has a plurality of mesas 704 extending in a direction away from the original chuck body 108. Thus, the refurbished electrostatic chuck 700 has distinct portions, namely, the original chuck body 108 and the new dielectric material 302. Both the original chuck body 108 and the new dielectric material 302 may comprise the same material such as aluminum oxide.

Implementations described herein disclose an improved refurbishment process using plasma spray with nanopowders in suspension slurry. The suspension slurry comprising small nano-sized powders or solid particles is atomized into a stream of fine droplets and injected directly into the plasma without a carrier gas. The droplets are dried in flight, calcined and melted in a single step. The droplets agglomerate to form drops of partially or totally melted dielectric material. The molten drops of the dielectric material are then deposited on the exposed electrostatic chuck body to form a hard and dense deposit of the dielectric material.

Unlike the conventional refurbishment process where the number of removal of the dielectric material and geometric creation (e.g., mesas) is limited due to the thickness of the dielectric material for the electrostatic chuck body is fixed, the refurbishment process as discussed herein increases the life time of the electrostatic chuck by extending the number of refurbishments. Particularly, the refurbishment process at boxes 802 to 808 (or any particular box described above) may be repeated as many times as desired without being limited to the physical thickness of the dielectric material. Since the worn down materials can repetitively be replaced by a new dielectric material using suspension slurry plasma spray process, the electrostatic chuck can be refurbished many more times than the conventional refurbishment process. The dielectric deposition thickness is always the same even after multiple cycles of refurbishment process. The refurbishment process of this disclosure has been observed to be able to reduce the porosity in the dielectric material to under 1%, thereby avoiding high voltage break down on thin dielectrics. By refurbishing the electrostatic chuck, there is no need to purchase an entirely new electrostatic chuck. The refurbished electrostatic chuck will cost less than the new electrostatic chuck, yet have essentially the same resistivity and function substantially identical as the new electrostatic chuck.

While the foregoing is directed to implementations of the disclosed devices, methods and systems, other and further implementations of the disclosed devices, methods and systems may be devised without departing from the basic scope thereof, and the scope thereof is determined by the claims that follow.

1. A method for refurbishing an electrostatic chuck, comprising:
removing a first portion of an electrostatic chuck body to expose a second portion of the electrostatic chuck body, wherein the first portion has a first depth below a top surface of the electrostatic chuck body and the second portion has a second depth below the top surface of the electrostatic chuck body;
depositing a layer of dielectric material onto the second portion using a suspension slurry plasma spray process, the suspension slurry plasma spray process comprising:
producing a plasma discharge;
atomizing a suspension slurry of a dielectric material into a stream of droplets using an atomizing probe that uses a pressurized gas to shear the suspension slurry of the dielectric material into the stream of droplets, the suspension slurry comprising nano-sized solid particles of the dielectric material dispersed into a liquid or semi-liquid carrier substance;
injecting the stream of droplets into the plasma discharge to form partially melted drops; and
forming a layer of dielectric material onto the exposed second portion by projecting the partially melted drops onto the second portion of the electrostatic chuck body; and
selectively removing material from the layer of dielectric material to establish a new top surface.

2. The method of claim 1, further comprising:
after depositing a layer of dielectric material onto the second portion, roughening the layer of dielectric material.

3. The method of claim 2, wherein the roughened dielectric material has a surface roughness of between about 2 microinches and about 10 microinches.

4. The method of claim 1, wherein the dielectric material has a thickness of about 20 microns to about 60 microns.

5. The method of claim 1, wherein the nano-sized solid particles of the dielectric material has a diameter of about 1 micron to about 10 nanometer.

6. The method of claim 1, wherein removing a first portion of an electrostatic chuck body comprises removing a plurality of mesas formed on the top surface of the electrostatic chuck body.

7. The method of claim 1, wherein selectively removing material from the layer of dielectric material to establish a new top surface comprises:
forming a mask over the layer of dielectric material; and
bead blasting the layer of dielectric material exposed through the mask to form mesas.

8. The method of claim 7, further comprising polishing the new top surface, wherein polishing the new top surface comprises removing burrs from the mesas.

9. The method of claim 1, wherein the layer of dielectric material comprises aluminum oxide.

10. The method of claim 1, wherein the layer of dielectric material comprises aluminum nitride.

11. The method of claim 1, wherein injecting the stream of droplets into the plasma discharge is performed without the use of a carrier gas.

12. A refurbished electrostatic chuck refurbished by the method of claim 1.

13. A method for refurbishing an electrostatic chuck, comprising:
(a) removing a portion of an electrostatic chuck body to expose a base surface of the electrostatic chuck body;
(b) depositing a layer of dielectric material onto the base surface using a suspension slurry plasma spray process, the suspension slurry plasma spray process comprising:
producing a plasma discharge;
atomizing a suspension slurry of a dielectric material into a stream of droplets using an atomizing probe that uses a pressurized gas to shear the suspension slurry of the dielectric material into the stream of droplets, the suspension slurry comprising nano-sized solid particles of the dielectric material dispersed into a liquid or semi-liquid carrier substance;
injecting the stream of droplets into the plasma discharge directly to form partially melted drops; and
forming a layer of dielectric material onto the base surface by accelerating the partially melted drops with the plasma discharge towards the base surface of the electrostatic chuck body; and
(c) roughening the layer of dielectric material; and
(d) selectively removing material from the layer of dielectric material to establish a new top surface.

14. The method of claim 13, further comprising:
repeating (a) to (d).

15. The method of claim 13, wherein the roughened dielectric material has a surface roughness of between about 2 microinches and about 10 microinches.

16. The method of claim 13, wherein the dielectric material has a thickness of about 20 microns to about 60 microns.

17. The method of claim 13, wherein the nano-sized solid particles of the dielectric material has a diameter of about 1 micron to about 10 nanometer.

18. The method of claim 13, wherein the layer of dielectric material comprises aluminum oxide or aluminum nitride.

19. The method of claim 13, wherein injecting the stream of droplets into the plasma discharge is performed without the use of a carrier gas.

20. The method of claim 13, wherein selectively removing material from the layer of dielectric material to establish a new top surface comprises:
forming a mask over the layer of dielectric material; and
bead blasting the layer of dielectric material exposed through the mask to form mesas.
